(19) United States
(12) Patent Application Publication
(10) Pub. No.: US 2012/0299187 A1
(43) Pub. Date: Nov. 29, 2012

(54) Aluminum Bond Pad With Trench Thinning for Fine Pitch Ultra-Thick Aluminum Products

(75) Inventors: Kent Charles OERTLE, Phoenix, AZ (US); Wei Xia, Irvine, CA (US); Edward Law, Ladera Ranch, CA (US)

(73) Assignee: Broadcom Corporation, Irvine, CA (US)

(21) Appl. No.: 13/166,562

(22) Filed: Jun. 22, 2011

Related U.S. Application Data
(60) Provisional application No. 61/490,985, filed on May 27, 2011.

(51) Int. Cl. H01L 23/485; H01L 21/50

(52) U.S. Cl. 257/762; 438/612; 257/E23.02; 257/E21.499

(57) ABSTRACT

Embodiments of an aluminum pad thinning in bond pad for fine pitch ultra-thick aluminum pad structures are provided herein. Embodiments include a conductive structure formed on a substrate. A first passivation layer is formed over the substrate and the conductive structure, the first passivation layer having an opening formed over the conductive structure. An ultra-thick conductive structure having a thinned trench region formed over the opening of the first passivation layer. The ultra-thick conductive structure is in contact with the conductive structure. A second passivation layer formed over the first passivation region and the ultra-thick conductive structure. The second passivation layer having an opening formed over the thinned trench region of the ultra-thick conductive structure.

### CROSS-REFERENCE TO RELATED APPLICATIONS

The present application claims the benefit of U.S. Provisional Application No. 61/490,985, filed May 27, 2011, which is incorporated herein by reference in its entirety.

### FIELD OF THE INVENTION

This application relates generally to the fabrication of semiconductor devices, and more particularly to a fine pitch ultra-thick aluminum bond pad structure.

### BACKGROUND

Wire bonding is a process used by the semiconductor industry to provide electrical connections between an integrated circuit (IC) and a package or a circuit board during the fabrication process. Gold bond wires have been predominantly used in conjunction with aluminum bond pads for bonding ICs requiring smaller wire diameters over the past two decades due to their high performance and reliability. However, in recent years the price of gold has reached record highs causing an increase in the cost of fabricating IC devices.

The increased cost of fabricating IC devices has caused a migration within the semiconductor industry from gold bond wires to copper bond wires. Copper bond wires are a suitable replacement because they can be used at smaller or larger diameters while providing the same performance and reliability as gold bond wires without the high material cost. However, the use of copper bond wires in conjunction with aluminum bond pads create new challenges because copper requires more heat and force during the bonding process than gold. As a result, the bonding parameters of copper must be kept under tight control when a wire ball is attached to aluminum bond pads to prevent aluminum splash.

Aluminum splash is defined as the amount of aluminum displaced by the heat and force of a bonding process. The displacement of aluminum during bonding can cause bond pads to short circuit by fusing them together. Aluminum splash is an important consideration to take into account when designing ICs because aluminum splash restricts how close bond pads can be placed to one another.

Therefore, what is needed is an apparatus and a method for a fine pitch ultra-thick aluminum pad that prevents aluminum splash from short circuiting adjacent bond pads.

### SUMMARY

These and other problems are generally solved or circumvented, and technical advantages are generally achieved, by embodiments provided herein. An embodiment includes a conductive structure formed on a substrate and a first passivation layer formed over the substrate and the conductive structure. The first passivation layer includes an opening formed over the conductive structure. An ultra-thick conductive structure includes a thinned trench region formed over the opening of the first passivation layer. The ultra-thick conductive structure is in contact with the conductive structure. A second passivation layer formed over the first passivation region and the ultra-thick conductive structure. The second passivation layer includes an opening formed over the thinned trench region of the ultra-thick conductive structure.

In accordance with another embodiment, a method of forming an ultra-thick bond pad structure of a semiconductor device includes providing a semiconductor substrate, forming a conductive structure on a surface of the semiconductor substrate, forming a first passivation layer over the semiconductor substrate and the conductive structure, forming an opening through the first passivation layer to expose the conductive structure, and forming an ultra-thick conductive structure over the opening of first passivation layer. The ultra-thick conductive structure is in contact with the exposed conductive structure and the first passivation layer. The method further includes etching a trench within the ultra-thick conductive structure that is formed over the opening of the first passivation layer, forming a second passivation layer over the first passivation layer and ultra-thick conductive structure and the first passivation layer, forming a second opening in the second passivation layer to expose the trench of the ultra-thick conductive structure, forming an etching mask over the second passivation layer, thinning down the trench of ultra-thick conductive structure, by etching, using the etching mask and removing the etching mask from the second passivation layer.

In accordance with yet another embodiment, a bond pad structure of a semiconductor device includes a first conductive structure formed on a substrate and a first passivation layer is formed over the substrate and the first conductive structure. The first passivation layer includes an opening that exposes the first conductive structure. The bond pad structure of a semiconductor device also includes a second conductive structure having a trench formed over the opening of the first passivation layer. The trench of the second conductive structure being used as the bond pad. The bond pad structure of a semiconductor device further includes a second passivation layer formed over the first passivation layer and second conductive structure. The second passivation layer having an opening that exposes the trench of the second conductive structure.

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1a-1b illustrates cross-sectional views of conventional bond pad structures.

FIG. 1c illustrates cross-sectional views of a bond pad structure, according to embodiments of the present invention.

FIG. 1d illustrates a cross-sectional view of a bond pad structure with an elongated unthinned region for routing, according to embodiments of the present invention.

FIG. 2a-2j illustrates cross-sectional views of a bond pad structure, according to embodiments of the present invention.

FIG. 3 illustrates a flow chart of a method, according to embodiments of the present invention.

The present invention will be described with reference to the accompanying drawings. The drawing in which an element first appears is typically indicated by the leftmost digit(s) in the corresponding reference number.

### DETAILED DESCRIPTION

In the following description, numerous specific details are set forth in order to provide a thorough understanding of the invention. However, it will be apparent to those skilled in the art that the invention, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring aspects of the invention.

Reference in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

### Conventional Bond Pad Structures

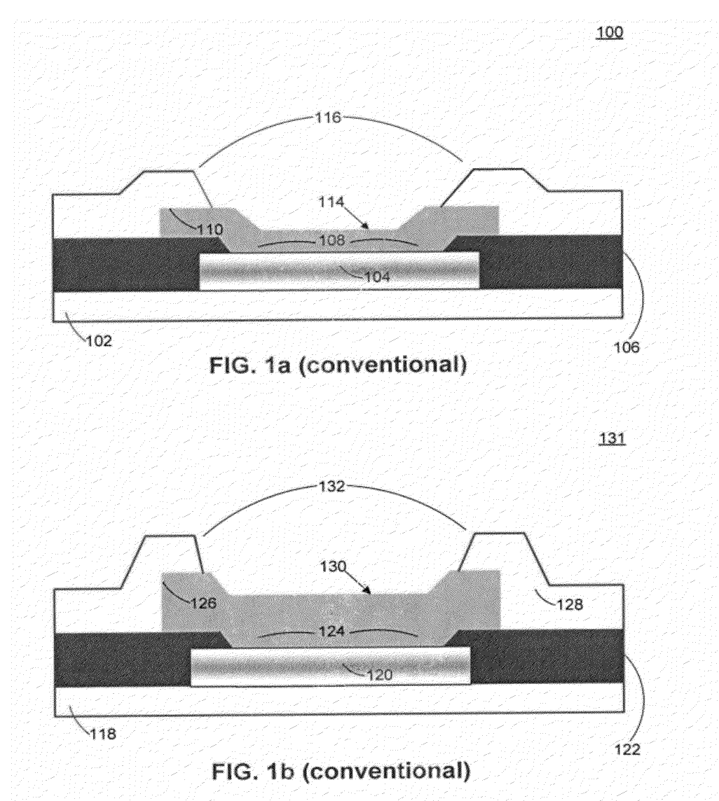

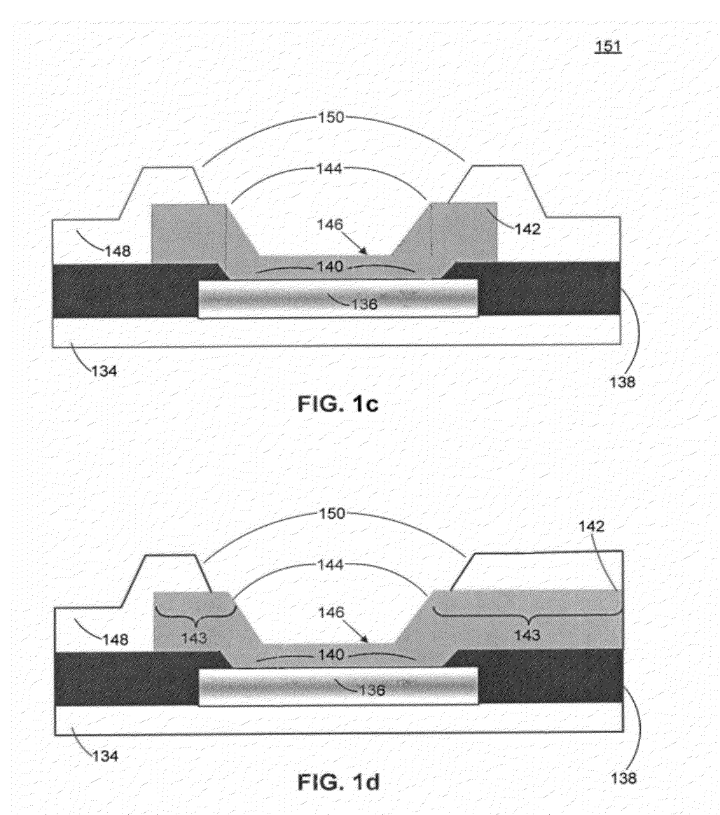

FIG. 1a illustrates a cross-sectional view of a 1st conventional bond pad structure 100. The 1^{st} conventional bond pad structure 100 includes a semiconductor substrate 102, a conductive layer 104, a first passivation layer 106 having an opening 108, an aluminum pad 110, and a second passivation layer 112 having an opening 116. The aluminum pad 110 of the bond pad structure 100 has a thickness between the ranges of 0.9 μm-1.7 μm. This conventional bond pad eliminates short circuits caused by aluminum splash by using a thin aluminum pad having low metal volume. This proposed solution enables fine pitch bond pads to be spaced closer together and allows more I/O ports to be placed on an IC device.

However, the aluminum pad is not optimal because of compatibility problems with products that require low resistance. The low metal thickness of the aluminum layer increases its resistance. Some products that are attached to the aluminum layer need low resistance for optimal performance. For example, the proposal solution is not practical for products having inductors because high resistance does not allow inductors to provide a high quality factor. Therefore, attaching these types of products to the aluminum pad 110 will not provide ideal inductors.

FIG. 1b illustrates a cross-sectional view of a 2^{nd} conventional bond pad structure 131. The 2^{nd} convectional bond pad structure 131 includes a semiconductor substrate 118, a conductive layer 120, a first passivation layer 122 including an opening 124, an ultra-thick aluminum pad 126, and a second passivation layer 128 including an opening 132. The ultra-thick aluminum pad 126 can have a thickness between the ranges of 3.5 μm-5 μm, which is greater than that of aluminum bond pad 110 and provides a lower resistance than aluminum bond pad 110. This conventional bond pad eliminates short circuits caused by aluminum splash by moving I/O spaces and wire bond pads further apart. This proposed solution also increases electro-migration performance and creates lower resistance properties across an IC device.

However, the proposed solution is not optimal because larger pitch bond pads must be used in order to take advantage of the ultra-thick aluminum pad. By way of example, I/O spaces must be placed further apart and larger pitch bond pads have to be used because the ultra-thick aluminum pad displaces more aluminum during the bonding process. Moreover, spacing the bond pads further apart reduces the amount of I/O available for a given IC device. For example, using larger pitch bond pad for devices that require a fixed amount of I/O increases the die size and cost of fabrication without providing gain to performance or functionality.

### A Fine Pitch Ultra-thick Bond Pad Structure

FIG. 1c illustrates a cross-sectional view of a fine pitch ultra-thick aluminum pad wire bond structure 151, according to embodiments of the present invention. The wire bond structure 151 includes a semiconductor substrate 134, a conductive structure 136, a first passivation layer 138 having an opening 140, an ultra-thick conductive structure 142, and a second passivation layer 148 having an opening 150. The semiconductor substrate 134 can be silicon. Alternatively, the semiconductor substrate 134 can also be made of germanium, and diamond, silicon carbide, gallium arsenide, indium arsenide, or indium phosphide. The semiconductor substrate (hereinafter referred to as substrate) 134 can have a plurality of device and interconnections (not shown).

The conductive structure 136 is formed on the substrate 134 using at least one layer of a conductive material. For example, the conductive structure 136 can be made of copper. Alternatively, the conductive structure 136 can also be formed from aluminum, zinc, titanium, gold and nickel or other suitable combinations of metals. By way of example, the conductive structure 136 can be used as a terminal or any other suitable conductive mechanism.

The first passivation layer 138 is formed over the silicon substrate 134 and the conductive structure 136. The first passivation layer 138 includes an opening 140 that exposes the conductive structure 136. By way of example, the first passivation layer 138 can be a formation of a hard non-reactive surface that inhibits corrosion from forming on metallics. For example, the first passivation layer 138 can be silicon oxide, silicon nitride or any other suitable material.

The ultra-thick conductive structure 142 is formed over the opening 140 of the first passivation layer 138. The ultra-thick conductive structure 142 is in contact with the exposed conductive structure 136. The ultra-thick conductive structure 142 can be an ultra-thick aluminum pad (UTAP) 142. Alternatively, the ultra-thick conductive structure 142 can also be aluminum alloys, titanium, tungsten, platinum, copper, metal silicide, other suitable metals, metals alloys and/or combinations thereof.

UTAP 142 includes a thinned trench region 144 having fine pitched sidewalls and a bottom 146. The bottom of the thinned trench region 144 is used as a bond pad 146. The thickness of the UTAP 142 in the thinned trench region 144 ranges from, but is not limited to, 1 μm-1.5 μm. Accordingly, the thinned trench region has a conductor thickness (e.g. 1 um-1.5 um) that is substantially less than the conductor thickness of the remainder (or non-thinned portion) of the ultra-thick conductive structure 142, which can range from, but is not limited to, 2.8 μm-4 μm. Other thicknesses could be used as will be understood by those skilled in the art(s), as long as the thickness of the thinned trench region 144 is thinner than that of the remainder (or the thick portions) of the UTAP 142, so as to remove or reduce bondpad splash during bonding as described herein. Using the thinned trench region 144 of UTAP 142 as the bond pad 146 reduces the amount of aluminum that is displaced during the bonding process, resulting in the elimination aluminum splash during the placement of the ball bond. Advantageously, the elimination of aluminum splash when using UTAP 142 allows wire bond pads to be placed closer together and creates more I/O for IC devices. As discussed above, the total thickness of UTAP 142 in the unthinned portion ranges from but is not limited to, 2.8 μm-4 μm. Advantageously, the metal properties of UTAP 142 increases electro-migration performance and provides lower resistance which, is useful to other IC devices that are attached, and can be used for higher current routing as described further below. The advantage is that the thinned trench region 144 is thinner than the unthinned region, which results in lower resistance for connectivity in the unthinned region, while providing a thinner region to lower splash during bonding and more bonds per unit area.

The second passivation layer 148 is formed over the first passivation layer 138 and the UTAP 142. The second passivation layer 148 can be a formation of a hard non-reactive surface that prevents corrosion from forming on metallics. By way of example, the second passivation layer 148 can be silicon oxide, silicon nitride or any other suitable material. The second passivation layer 148 can include an opening 150 that exposes the thinned trench region 144 of the UTAP 142.

In another embodiment of the present invention FIG. 1d illustrates a cross-sectional view of a fire pitch ultra-thick aluminum pad wire bond structure 151. The numbered elements in FIG. 1d correspond to the numbered elements in FIG. 1c. UTAP 142 includes a thinned trench region 144 and unthinned region 143. Unthinned region 143 of UTAP 142 can be shortened or elongated. By way of example, unthinned regions 143 of UTAP 142 can be used for global routing, detail routing and any other suitable form of routing, and offers the advantage of a thicker metal layer for higher current handling.

In another embodiment of the present invention the bond pad structure can be used for a flip chip process instead of the wire bonding process.

### Method of Fabrication

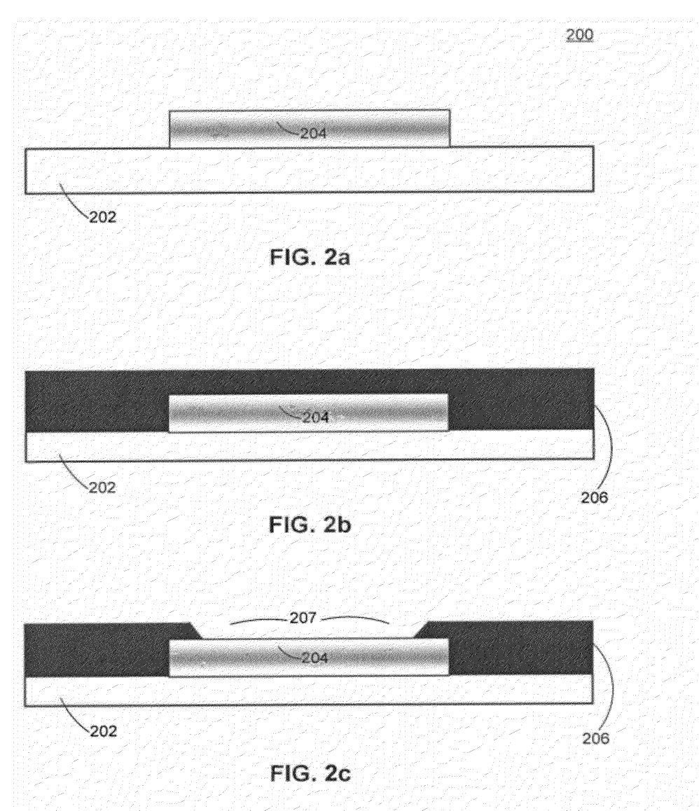

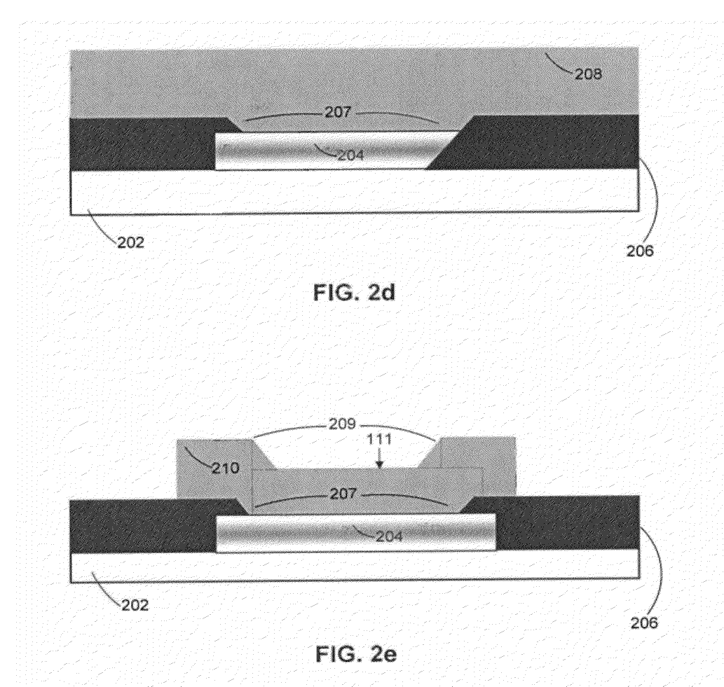

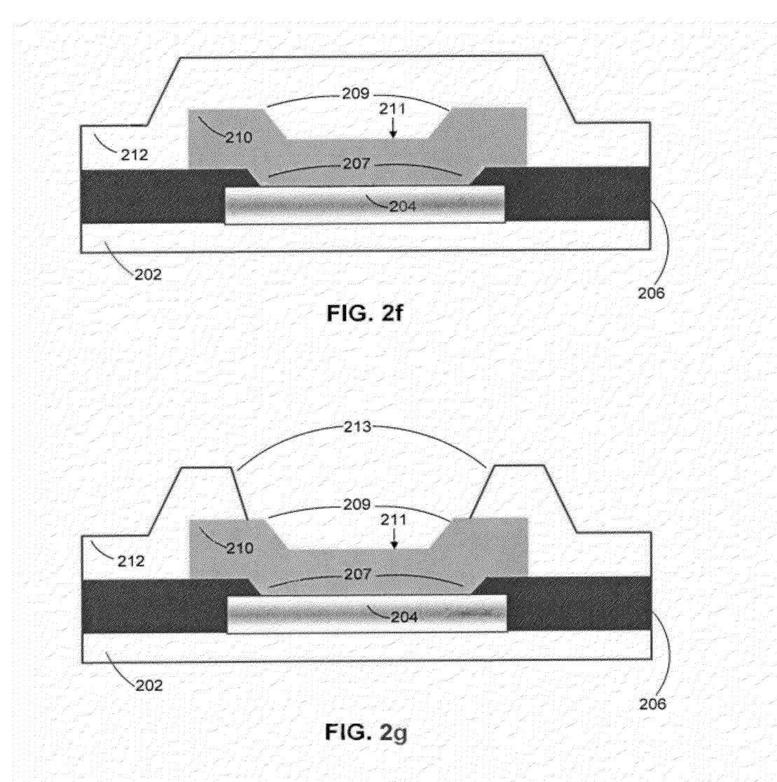

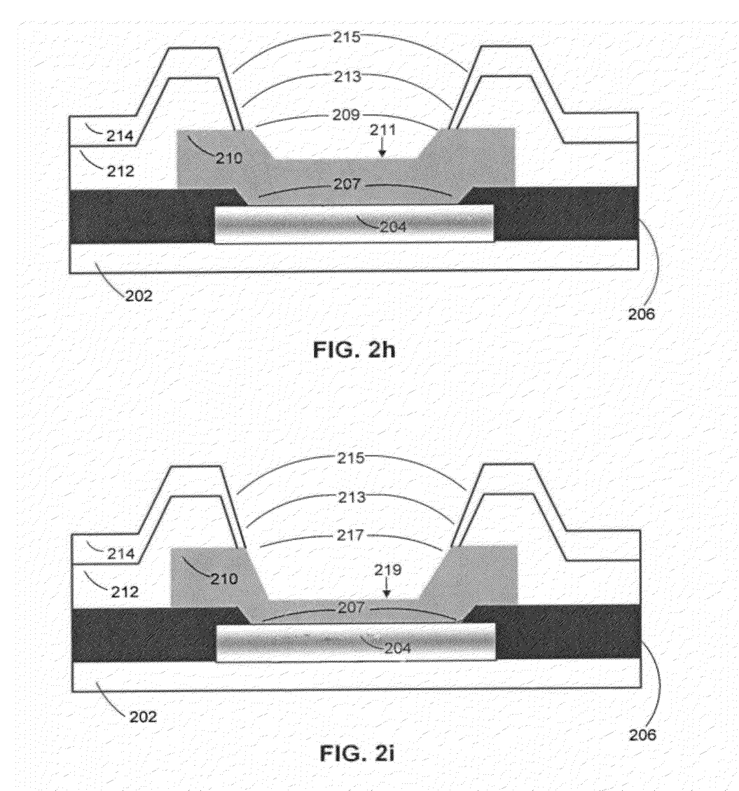

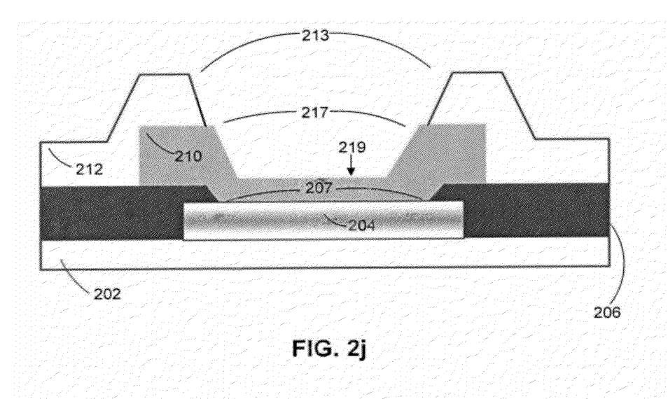

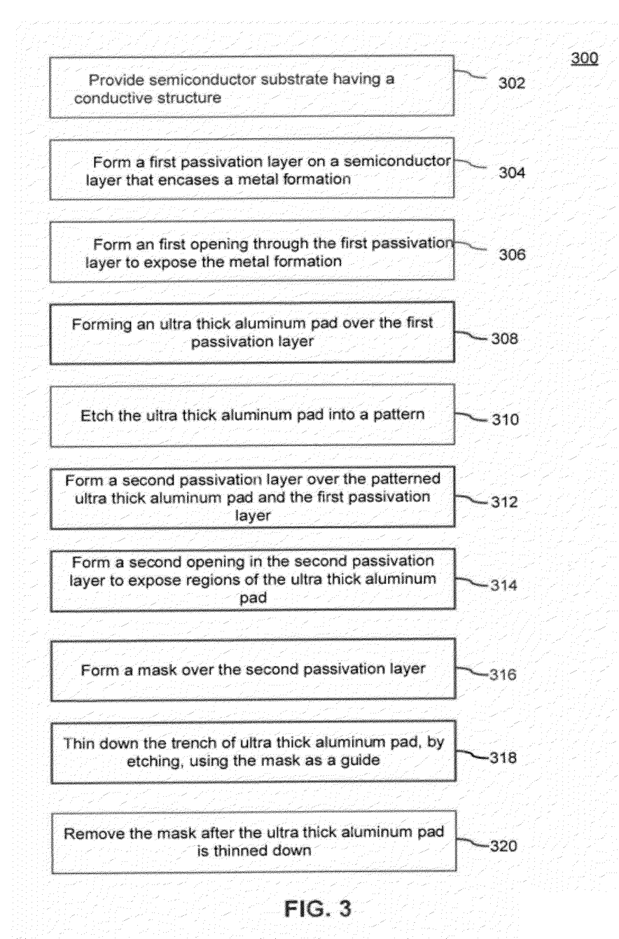

FIGS. 2a-2j provide exemplary devices that correspond to fabrication steps of method 300. FIG. 3 is a flowchart depicting an exemplary method 300, according to embodiments of the present invention. For example, method 300 can be used to fabricate a fine pitch ultra-thick aluminum pad having a thinned bond region. The method 300 may not occur in the order shown, or require all the steps. The method 300 begins at step 302 where a substrate 202 is provided for the formation of a conductive structure 204 as shown in FIG. 2a. The substrate 202 can include silicon, germanium, and diamond. Alternatively, the substrate 202 can also include compound semiconductors such as, silicon carbide, gallium arsenide, indium arsenide, or indium phosphide.

The conductive structure 204 is formed on a surface of substrate 202. By way of example, at least one layer of conductive material can be deposited on the surface of the substrate 202 and an etching technique can be applied to form the conductive structure 204. For example, the conductive material can be deposited on the substrate 202 using a deposition process such as, atomic layer deposition, chemical vapor deposition, physical vapor disposition, plasma enhanced atomic layer deposition, molecular beam epitaxy, ion beam assisted deposition, or other suitable deposition processes. Once the conductive material is deposited onto a surface of the substrate 202 the conductive structure 204 can be patterned by applying a wet etching process, a photochemical etching process or a dry etching process. The conductive structure 204 can be formed of copper. Alternatively, the conductive structure 204 can also be aluminum, zinc, titanium, gold and/or other suitable combinations of metals.

In step 304, the first passivation layer 202 is formed over the substrate 202 and encases the conductive structure 204 as shown in FIG. 2b. The first passivation layer 206 can be a formation of a hard non-reactive surface that inhibits corrosion from forming on metallics. For example, the first passivation layer 206 can be silicon oxide, silicon nitride or any other suitable material. The first passivation layer 206 can be formed by using various deposition processes such as, atomic layer deposition, chemical vapor deposition, physical vapor disposition, plasma enhanced atomic layer deposition, molecular beam epitaxy, ion beam assisted deposition, or other suitable deposition processes.

In step 306, an opening 207 can be formed within the first passivation layer 206 that exposes the conductive structure 204 as shown in FIG. 2c. By way of example, a masked region can be identified within the first passivation layer 206 that is over the conductive structure 204. The masked region can be used to create the opening 207 within the first passivation layer 206 by applying a wet etching process or a photochemical etching process. In another example, a dry etching process can be used within the masked region to form an opening that requires directional or anisotropical formations.

In step 308, the ultra-thick conductive layer (UTCL) 208 is deposited over the first passivation layer 206 as shown in FIG. 2d. UTCL 208 is in contact with the exposed surface of the conductive structure 204. UTCL 208 can be formed using one of various deposition processes such as atomic layer deposition, chemical vapor deposition, physical vapor disposition, plasma enhanced atomic layer deposition, molecular beam epitaxy, ion beam assisted deposition, or other suitable deposition processes. UTCL 208 can be an ultra-thick aluminum layer. Alternatively, UTCL 208 can also be formed using aluminum alloys, titanium, tungsten, platinum, copper, metal silicide, other suitable metals and/or metals alloys and combinations of above-mentioned.

Proceeding to step 310, where ultra-thick aluminum layer 208 is formed into an ultra-thick aluminum pad (UTAP) 210 having a trench 209 as shown in FIG. 2e. The trench 209 of the UTAP 210 includes pitched sidewalls and a bottom surface 211. UTAP 210 can be patterned using a mask in conjunction with various etching processes such as, dry etching, plasma etching or wet etching.

In step 312, the second passivation layer 212 is formed over the first passivation layer 206 and UTAP 210 as shown in FIG. 2f. The second passivation layer 212 can be a formed of a hard non-reactive surface that prevents corrosion from forming on metallics. By way of example, the second passivation layer 212 can be silicon oxide, silicon nitride or any other suitable material. The second passivation layer 212 can be deposited by using a deposition process such as atomic layer deposition, chemical vapor deposition, physical vapor disposition, plasma enhanced atomic layer deposition, molecular beam epitaxy, ion beam assisted deposition, or other suitable deposition processes.

Proceeding to step 314, where an opening 213 is formed within the second passivation layer 212 over the trench 209 of UTAP 210 as shown in FIG. 2g. The opening 213 of the second passivation layer exposes the trench 209 of UTAP 210. For example, the opening 213 within the second passivation layer 212 can be formed using a variety of etching techniques such as, wet etching, plasma etching, photochemical etching and dry etching. Masking and photolithographic techniques can also be used in conjunction with various etching processes to form the opening 213 within the second passivation layer 212.

In step 316, a masking layer can be formed over the second passivation layer 212 as shown in FIG. 2h. The masking layer can be used to protect the second passivation layer 212 from an etching process. By way of example, the masking layer 214 can be used as a guide during the etching process. The masking layer 214 can include an opening 215 located over the trench 209 of the UTAP 210.

In step 318, the trench 209 of the UTAP 210 is thinned down by using an etching process like one described above, as shown in FIG. 2i. The thinned trench region 217 is etched down to the thickness that range from, but are not limited to, 1 μm-1.5 μm. Other thicknesses could be used as will be understood by those skilled in the art, as long as the thickness of the thinned trench region 144 is thinner than that of the remainder (or the thick portions) of the UTAP 142, so as to remove or reduce bondpad splash during bonding as described herein. The thinned trench region 217 of the UTAP 210 forms a fine pitch bond pad region 219.

In step 320, the masking layer 214 is removed from the second passivation layer 212 as shown in FIG. 2j. The masking layer 214 can be removed by using an etching process. The etching process can be one of the abovementioned etching processes.

### CONCLUSION

It is to be appreciated that the Detailed Description section, and not the Abstract section, is intended to be used to interpret the claims. The Abstract section is intended to be used to interpret the claims. The Abstract section may set forth one or more but not all exemplary embodiment of the present invention as contemplated by the inventor(s), and thus, is not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

What is claimed is:

1. An apparatus formed on a substrate, comprising:
a conductive structure formed on the substrate;
a first passivation layer formed over the substrate and the conductive structure, the first passivation layer having an opening formed over the conductive structure,
an ultra-thick conductive structure having a thinned trench region formed over the opening of the first passivation layer;
wherein the ultra-thick conductive structure is in contact with the conductive structure; and;
a second passivation layer formed over the first passivation layer and the ultra-thick conductive structure, the second passivation layer having an opening that formed over the thinned trench region of the ultra-thick conductive structure.

2. The apparatus of claim 1, wherein the conductive structure comprises copper.

3. The apparatus of claim 1, wherein the ultra-thick conductive structure is an ultra-thick aluminum pad.

4. The apparatus of claim 1, wherein the ultra-thick conductive structure has a maximum thickness that ranges from 2.8 μm-3.6 μm.

5. The apparatus of claim 1, wherein the thinned trench region of the ultra-thick conductive structure has a thickness that ranges from 1 μm-1.45 μm.

6. The apparatus of claim 1, wherein the thinned trench of the ultra conductive structure has pitched walls.

7. The apparatus of claim 1, wherein a bottom surface of the thinned trench region is used as a bond pad.

8. The apparatus of claim 1, wherein the first passivation layer and second passivation layer comprises at least one of the following: silicon dioxide or silicon nitride.

9. A method of forming a bond pad structure on a semiconductor substrate, comprising:
forming a conductive structure on the semiconductor substrate:
forming a first passivation layer over the semiconductor substrate and the conductive structure, the first passivation layer encases the conductive structure;
forming an opening through the first passivation layer to expose the conductive structure;
forming an ultra-thick conductive structure over the opening of first passivation layer, the ultra-thick conductive structure being in contact with the exposed conductive structure and the first passivation layer;
etching a trench within the ultra-thick conductive structure that is formed over the opening of the first passivation layer;
forming a second passivation layer over the first passivation layer and ultra-thick conductive structure and the first passivation layer;
forming a second opening in the second passivation layer to expose the trench of the ultra-thick conductive structure;
forming an etching mask over the second passivation layer,
thinning down the trench of ultra-thick conductive structure, by etching, using the etching mask; and
removing the etching mask from the second passivation layer.

10. The method of claim 9, wherein the semiconductor substrate comprises silicon.

11. The method of claim 9, wherein the conductive structure comprises at least one of the following: copper, nickel, titanium or gold.

12. The method of claim 9, further comprising using the thinned trench of the ultra-thick conductive structure as a bond pad.

13. The method of claim 9, wherein the thickness of the thinned trench of the ultra-thick conductive structure ranges from 1 μm-1.45 μm.

14. The method of claim 9, wherein the maximum thickness of the ultra-thick conductive structure ranges from 2.8 μm-3.6 μm.

15. The method of claim 9, wherein the ultra-thick conductive structure is an ultra-thick aluminum pad.

16. The method of claim 9, wherein passivation layer is silicon dioxide or silicon nitride.

17. A bond pad structure, comprising:
a first conductive structure formed on a substrate;
a first passivation layer is formed over the substrate and the first conductive structure, the first passivation layer having an opening that exposes the first conductive structure;
a second conductive structure formed over the opening of the first passivation layer having a trench; the trench of the second conductive structure being used as the bond pad; and
a second passivation layer formed over the first passivation layer and second conductive structure, the second passivation layer having an opening that exposes the trench of the second conductive structure.

18. The bond pad structure of claim 17, wherein the first conductive structure comprises copper.

19. The bond pad structure of claim 17, wherein the second conductive structure is an ultra-thick aluminum pad.

20. The bond pad structure of claim 17, wherein the thickness of the second ultra-thick conductive structure ranges from 2.8 μm-3.6 μm.

21. The bond pad structure of claim 17, wherein the trench of the second conductive structure has a thickness ranging from 1 μm-1.45 μm.

22. The bond pad structure of claim 17, wherein the trench of second conductive structure has pitched walls.

23. The apparatus of claim 1, wherein the thinned trench region is located substantially in the center of the ultra-thick conductive structure and has a conductor thickness that is substantially less than a conductor thickness of the remainder of the ultra-thick conductive structure.

24. The apparatus of claim 1, wherein the remainder of the ultra-thick conductive structure is used for high current conductor routing.

25. The bond pad structure of claim 17, wherein the trench has a conductor thickness that is substantially less than a conductor thickness of the remainder of the second conductive structure.
